(19) United States
(12) Patent Application Publication
(10) Pub. No.: US 2008/0286441 A1
(43) Pub. Date: Nov. 20, 2008

(54) Apparatus and method for rotational coating

(75) Inventors: Woo Sok Chang, Lexington, MA (US); Christos Monovoukas, Lexington, MA (US); Reto Schoeb, Rudolfstetten (CH)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Levitronix LLC, Waltham, MA (US)

(21) Appl. No.: 11/800,406

(22) Filed: May 4, 2007

(30) Foreign Application Priority Data
Feb. 14, 2007 (EP) 07102354.3

(51) Int. Cl. C23C 16/52; B05C 11/00

(52) U.S. Cl. 427/8; 118/712

(57) ABSTRACT

An apparatus for the rotational coating of a surface of a substrate with a fluid, in particular the surface of a wafer with a polymer liquid, especially with a photoresist includes a rotary plate (2) for receiving the substrate (11), a drive device (3) for rotating the rotary plate (2), a dispensing nozzle (4) for the application of a predeterminable quantity of fluid onto the surface of the substrate (11) for the purpose of forming a layer (12) and also a pump (5) for conveying the fluid, the pump being connectable, on the one hand, to a source (20) for the fluid and, on the other hand, to the dispensing nozzle (4). A viscosimeter (6) is provided with which the actual viscosity of the fluid can be determined by physical measurement prior to the application of the fluid. Furthermore a corresponding method is proposed.

This application claims the priority of European Patent Application No. 07102354.3, filed Feb. 14, 2007, the disclosure of which is incorporated herein by reference.

The invention relates to an apparatus and to a method for the rotational coating of a surface of a substrate with a fluid in accordance with the pre-amble of the independent claim of the respective category. In particular the invention relates to an apparatus and to a method for the rotational coating of a surface of a wafer with a polymer liquid, especially with a photoresist.

In semiconductor technology and in microelectronics, the method of rotation coating (spin coating) is for example used during the manufacture of integrated circuits, in order to produce a layer on the surface of a substrate by means of a fluid.

For the manufacture of integrated circuits or microelectronic structures it is necessary to transfer geometric forms, such as conductor tracks, onto the wafer. This takes place as a rule with the aid of a lithographic process in which first of all a thin layer of a photoresist (also termed photopaint) is applied to the surface of the wafer. After it is dried, the desired geometric structure is exposed by illuminating this layer with electromagnetic radiation, normally UV light, through a mask. At positions where the mask does not cover the photoresist layer, its solubility is either increased by the radiation (positive photoresist) or reduced (negative photoresist), so that in the subsequent processing step either the regions not covered during the exposure or the covered regions are dissolved away.

During spin coating, the layer is generated on the surface of the wafer by arranging the wafer on a rotary plate (chuck), by setting the rotary plate rotating and by then applying, by means of a dosing device above the centre of the wafer, a predeterminable quantity of a polymer liquid which contains a solvent in addition to the polymer. Through the rotation of the rotary plate, which normally takes place at 100 to 6000 rpm, the polymer liquid distributes itself as a thin layer on the wafer surface. In order to generate a solid layer, the solvent must subsequently be removed, which can be assisted by rotation—typically at lower speeds of rotation—or by heating the wafer or the process chamber. Such processes are, for example, disclosed in U.S. Pat. No. 6,662,466 or in US-A-2004/0009295.

An important aspect in the manufacture of photoresist layers is that the variation in the layer thickness considered over the entire wafer surface should be kept as small as possible. This is based, amongst other things, on the fact that one wishes to use light of the shortest possible wavelength as a result of the extremely small structures which are exposed on the wafer, with the depth of sharpness during the exposure being very small, for example 150 nm.

Moreover, one endeavors to make the layers very thin and to use the photoresist as efficiently as possible because this is a relatively expensive substance. Spinning away of the photoresist from the wafer surface should be avoided as far as possible. Accordingly, one is concerned with setting the parameters which influence the thickness of the layer that is aimed at as accurately as possible. These parameters include the rotational speed of the rotary plate, the temperature of the wafer and the viscosity of the polymer liquid to name just a few. The viscosity in turn normally depends strongly on the temperature but also on the composition of the polymer liquid. It can indeed be the case that within a supply flask for the polymer solution its viscosity changes because the ratio of solvent in the polymer is not constant spatially and/or time-wise.

In order to achieve a layer thickness which is as homogenous as possible it is proposed in US-A-2004/0009295 to first manufacture a plurality of samples in which the coating is consciously changed by the stepwise changing of individual parameters and subsequently to determine the ideal parameters by evaluating the empirically obtained data.

In U.S. Pat. No. 6,662,466 it is proposed, for the drying of the polymer, to measure the temperature of the polymer material, the substrate temperature and the environmental temperature in the vicinity of the substrate. If the environmental temperature changes, the substrate temperature, the polymer temperature, the environmental temperature or the rotational speed during the drying of the polymer are correspondingly adapted.

A similar problem exists with the manufacture of thin layers of the most even thickness possible on a substrate, for example also in the manufacture of CDs or DVDs. In this respect it is proposed, in U.S. Pat. No. 6,814,825, to first apply a liquid layer to a first substrate, to then rotate the first substrate and to then deposit a second substrate on the liquid layer and to spin off excess liquid by rotation. The resulting layer thickness is measured. If deviations are determined from the desired value, then the substrate temperature or the temperature of the liquid for the layer is correspondingly changed.

Starting from this prior art, it is an object of the invention to propose an apparatus and a method for the rotational coating of the surface of a substrate with which thin layers of the most even thickness possible can be generated. In particular the apparatus and the method should be suitable for the coating of a surface of a wafer with a polymer liquid, especially with a photoresist.

The subject matter of the invention which satisfies this object from an apparatus viewpoint and from a method viewpoint is characterized by the independent claims of the respective category.

Thus, in accordance with the invention, an apparatus is proposed for the rotational coating of a surface of a substrate with a fluid, in particular the surface of a wafer with a polymer liquid, especially with a photoresist, the apparatus including a rotary plate for receiving the substrate, a drive device for rotating the rotary plate, a dispensing nozzle for the application of a predeterminable quantity of fluid onto the surface of the substrate for the purpose of forming a layer and also a pump for conveying the fluid, the pump being connectable, on the one hand, to a source for the fluid and, on the other hand, to the dispensing nozzle. A viscosimeter is provided with which the actual viscosity of the fluid can be determined by technical measurement prior to the application of the fluid.

Since the viscosity of the fluid is one of the most important factors in spin coating which influence the layer thickness and/or the homogeneity of the layer thickness, it can be ensured, through the detection by technical measurement of the actual viscosity by means of the viscosimeter, that fluctuations in the viscosity of the fluid can be detected prior to its application to the surface to be coated. Thus, inhomogeneities in the layer thickness, which are caused by variations in the viscosity, can be at least significantly reduced. Since the viscosity is determined by technical measurement it is also immaterial whether its fluctuations originate from a change of the temperature of the fluid or a change in the composition of the fluid or from other changes. Through the viscosimeter every change in the viscosity can be detected irrespective of its cause. Surprising in this connection is the recognition that with a viscosimeter—also with an online measurement—fluctuations in the viscosity can be detected with sufficient accuracy. If it is found that the viscosity of the fluid has changed, or has changed too greatly, then countermeasures can be taken. For example the application of the fluid to the substrate can be stopped so that no faulty coating of the substrate or unsatisfactory coating of the substrate quality-wise arises.

A control device is preferably provided which is connected signal-wise to the viscosimeter and, on deviation of the viscosity of the fluid from a desired value, introduces a compensation with which variations in the thickness of the layer to be applied to the surface are counteracted. Through such a compensation it is possible to compensate detected changes in the viscosity by the variation of parameters, so that the coating can be carried out and the desired layer thickness can be realized. Such compensations can, for example, directly change the viscosity of the fluid or other parameters which then compensate the change caused by the viscosity fluctuation.

It is advantageous when a tempering process is provided for changing the temperature of the fluid because in this way the viscosity of the fluid can be influenced in a simple manner.

In a preferred embodiment, the rotary plate for receiving the substrate is provided in a process chamber, with a climate control unit being further provided, with which at least the temperature in the process chamber can be set. In this manner at least the temperature of the substrate can namely be controlled. Other relevant parameters for the layer thickness that is achieved can optionally also be set, for example the humidity.

In a particularly preferred embodiment, a supply unit is provided as the source for the fluid there being a first supply container for a first component of the fluid, a second supply container for a second component of the fluid, a mixing device for the through-mixing of the components of the fluid and also a control and regulating unit with which the quantity ratio of the components of the fluid can be set. This design namely permits the viscosity of the fluid to be set in that its composition is changed. For example, in the case of photoresist as a fluid the ratio of polymer to solvent can be changed in order in this way to change the viscosity of the fluid.

In this design the viscosimeter can advantageously be provided in the supply unit. In this way it is for example possible to first circulate the fluid in the supply unit for a sufficient period of time until the actual value of the viscosity corresponds with the desired value and to then first supply the fluid to the dispensing nozzle.

In practice, it is particularly favorable when the compensation includes at least one of the following measures: changing of the temperature of the fluid, changing of the rotational speed of the rotary plate, changing of the temperature in the process chamber; changing of the composition of the fluid by changing the quantity ratio of the components of the fluid.

In accordance with the invention a method is further proposed for the rotation coating of a surface of a substrate with a fluid, in particular the surface of a wafer with a polymer liquid, especially with a photoresist, in which method the substrate is arranged on a rotary plate, the rotary plate is rotated, a predeterminable quantity of the fluid is applied with a dispensing nozzle onto the surface of the substrate for the purpose of formation of a layer, with the fluid being conveyed by means of a pump from a source for the fluid to the dispensing nozzle. Prior to the application of the fluid its actual viscosity is determined by a technical measurement by means of a viscosimeter.

The explanations with respect to the apparatus apply in the same sense and manner also for the method.

For the above named reasons, it is also preferred in the method of the invention for the actual viscosity of the fluid to be compared with a desired value by means of a control device which is connected signal-wise to the viscosimeter and, in the event of a deviation, for a compensation to be introduced with which variations in the thickness of the layer to be applied to the surface can be counteracted.

From a technical method viewpoint it is also an advantageous variant when the actual viscosity is determined by a technical measurement by means of a viscosimeter in a supply unit provided as a source for the fluid.

For the compensation at least one of the following measures is preferably carried out: changing of the temperature of the fluid, changing of the rotational speed of the rotary plate, changing of the temperature in a process chamber for the rotary plate; changing of the composition of the fluid by changing the quantity ratio of the components of the fluid.

In accordance with the invention a method is further proposed for the rotational coating of a surface of a substrate with a fluid, in particular of the surface of a wafer with a polymer liquid, especially with a photoresist, said fluid comprising a solid, in which method the substrate is arranged on a rotary plate, the rotary plate is rotated, a predeterminable quantity of the fluid is applied with a dispensing nozzle onto the surface of the substrate for the purpose of formation of a layer, with the fluid being conveyed by means of a pump from a source for the fluid to the dispensing nozzle, wherein prior to the application of the fluid its actual viscosity is determined by a physical measurement by means of a viscosimeter and wherein the actual viscosity of the fluid is compared with the desired value by means of a control device which is connected signal-wise to the viscosimeter and, in the case of a deviation, a compensation is introduced with which variations in the thickness of the layer to be applied to the surface is counteracted, said compensation being based upon the relationship

t=K*S*η^{1/3}*ω^{-2/3}*R^{-2/3}

where t represents the thickness of the layer, K being a constant, S represents the fraction of said solid in the fluid, η represents the dynamic viscosity of the fluid, ω represents the rotational speed of the rotary plate, and R designates the radius of the substrate.

Preferably, the method comprises changing the fraction of said solid in the fluid.

The fraction of said solid may be determined by a physical measurement.

It is an advantageous variant when the relationship t=K*S*η^{1/3}*ω^{-2/3}*R^{-2/3} for the thickness of the layer is linearized.

A closed loop control for controlling the thickness of the layer can advantageously be provided.

Further advantageous measures and preferred embodiments of the invention can be seen from the dependent claims.

In the following, the invention will be explained in more detail with respect to embodiments and with reference to the drawing, both from the point of view of the apparatus and also from the point of view of a technical method. In the schematic drawing there is shown, partly in section:

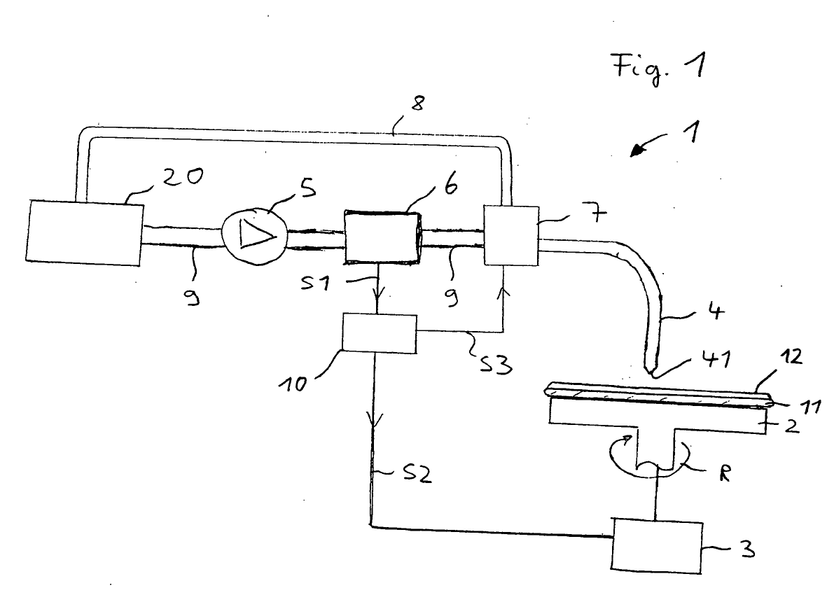

FIG. 1 a first embodiment of an apparatus in accordance with the invention for rotational coating,

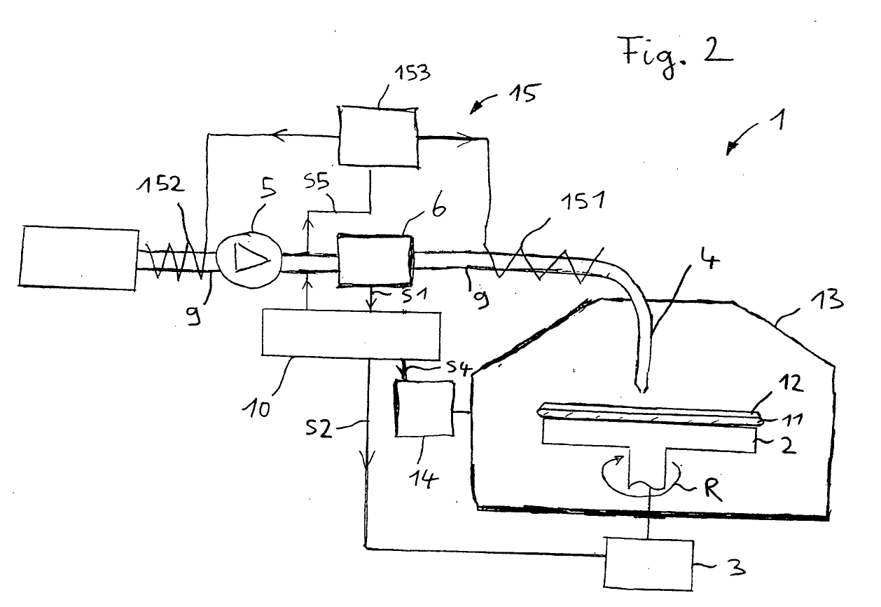

FIG. 2 a second embodiment of an apparatus in accordance with the invention for rotational coating,

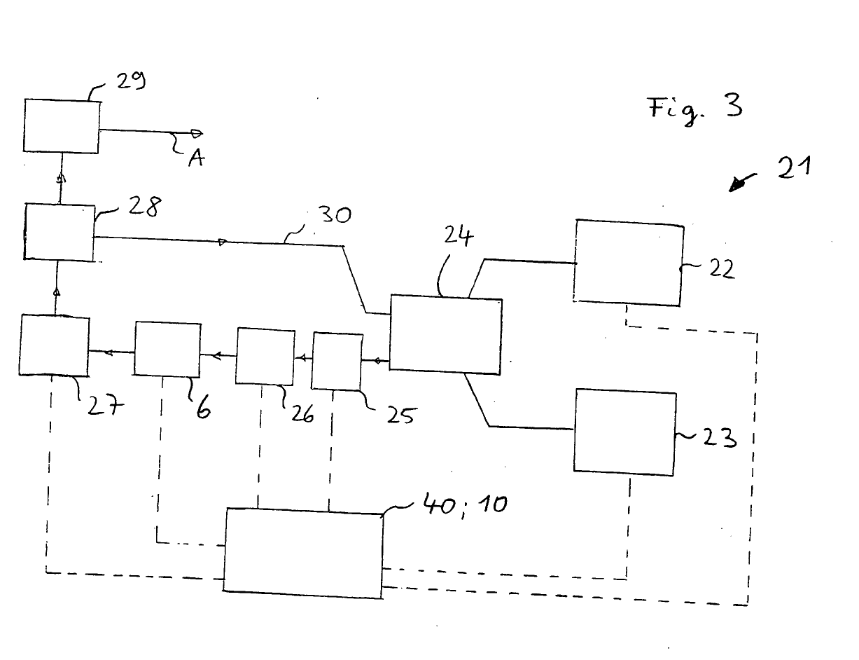

FIG. 3 an embodiment of a supply unit for the apparatus of the invention,

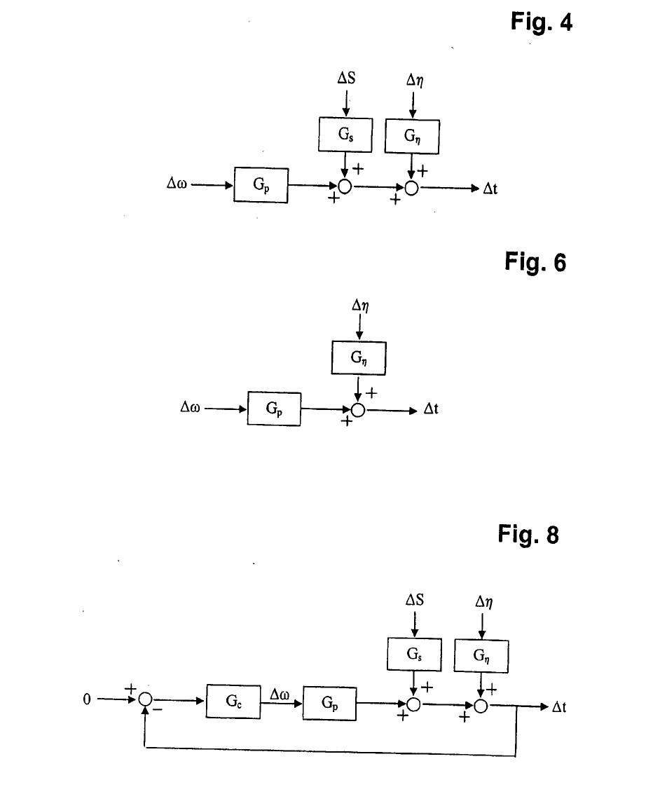

FIG. 4 a block diagram of a film thickness control device under external disturbances,

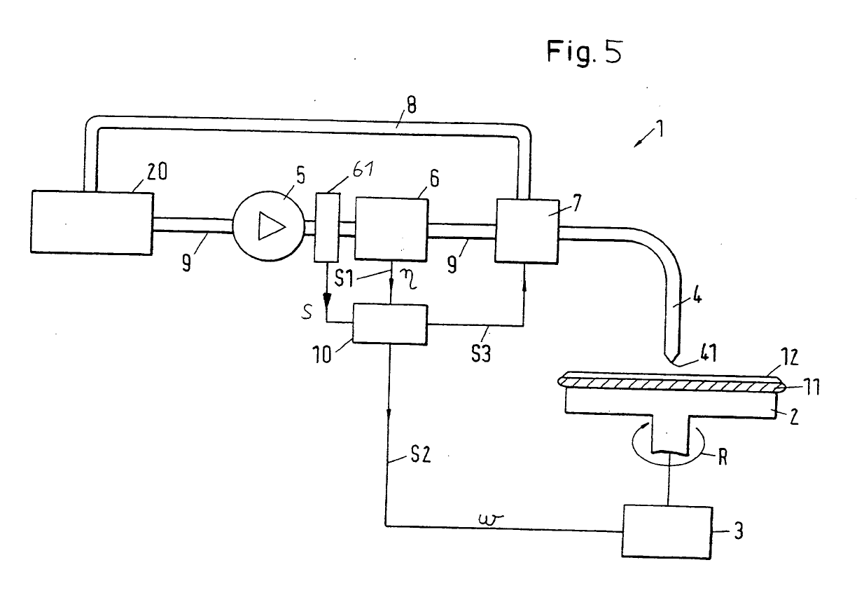

FIG. 5 an embodiment of an apparatus in accordance with the invention for a film thickness control according to FIG. 4,

FIG. 6 a block diagram of a film thickness control device under viscosity variation,

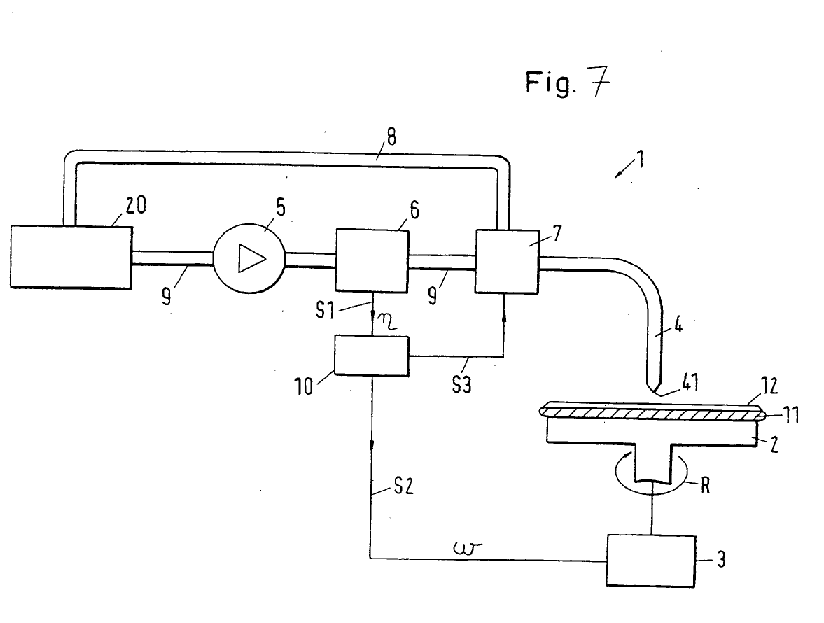

FIG. 7 an embodiment of an apparatus in accordance with the invention for a film thickness control according to FIG. 6,

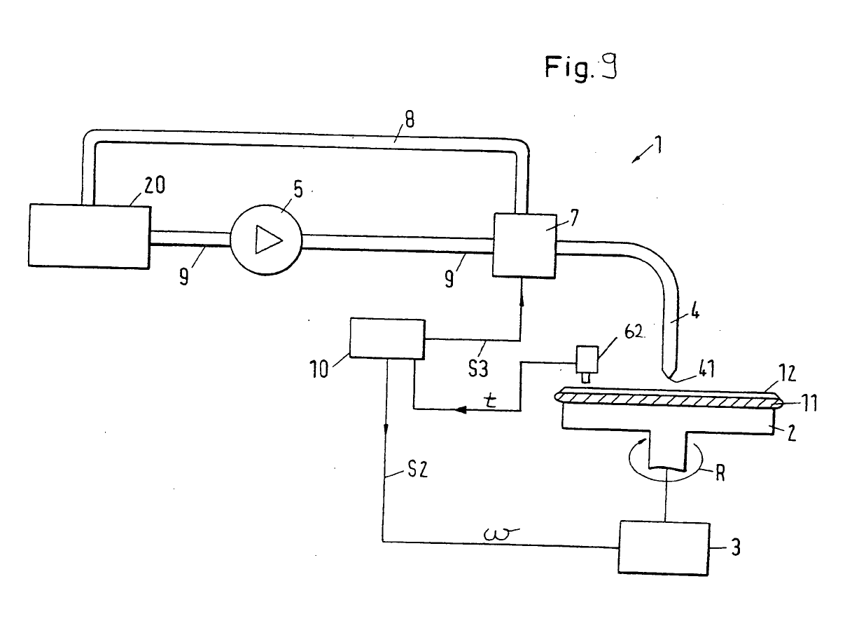

FIG. 8 a block diagram of a film thickness feedback control device (closed loop control), and

FIG. 9 an embodiment of an apparatus in accordance with the invention for a film thickness control according to FIG. 8,

Through the invention, an apparatus and a method for the rotational coating of the surface of a substrate with a fluid are proposed. In the following reference will be made to a case which is particularly important in practice in which the surface to be coated is the surface of a wafer and the fluid is a photoresist with which the wafer is to be coated in order to subsequently expose the desired structures on the wafer. It will be understood, however, that the invention is not restricted to such applications but rather is also suitable for other processes in which, in particular, a thin layer of a fluid should be generated on the surface of the substrate by means of rotation coating. Other examples are the manufacture of CDs or DVDs. In this connection the layer that is produced can also be a bond layer or a connection layer onto which then a second substrate is applied. Naturally, fluids other than photoresist can also be processed with the apparatus of the invention or the method of the invention, in particular polymer liquids.

FIG. 1 shows, in a schematic illustration, a first embodiment of an apparatus in accordance with the invention for the spin coating of a surface of a substrate which is designated as a whole with the reference numeral 1. The apparatus 1 includes a rotary plate 2, which is also termed a chuck and which serves to receive a substrate 11, here a wafer 11. A layer 12 of a liquid, here a photoresist, should be generated on the wafer 11 and should have the smallest possible variations in its thickness. In the operating state, the wafer 11 is held by methods known per se, for example by means of suction or vacuum technology on the rotary plate 2.

Furthermore, a drive device 3 is provided with which the rotary plate can be rotated as is indicated by the arrow with the reference character R.

In accordance with the representation, a dispensing nozzle 4 is provided above the rotary plate 2. Through this nozzle, a predeterminable quantity of the fluid is applied onto the surface of the substrate 11 in order to produce the layer 12 there. In the present case, the dispensing nozzle 4 is arranged to be stationary and indeed such that its outlet opening 41, through which the fluid emerges, is located above the centre of the rotary plate 2. However, designs are also possible in which the dispensing nozzle 4 is movably arranged relative to the rotary plate 2, so that its position can be controllably changed with respect to the rotary plate 2.

Furthermore, a pump 5 is provided with which the fluid can be conveyed from a source 20 for the fluid through a feed 9 formed as a line to the dispensing nozzle 4. The pump 5 is preferably designed as a metering pump with which, in each case, a predeterminable quantity of fluid can be conveyed to the dispensing nozzle 4 for the coating of a wafer 11. The pump can naturally also be designed in a manner known per se as a filter pump with an integrated filter or in the form of a pump-filter-pump unit in which the first pump realizes the pressure build-up for the flow through the filter and the second pump serves to convey the fluid to the dispensing nozzle 4.

In accordance with the invention the apparatus 1 includes a viscosimeter 6 with which the actual viscosity of the fluid can be determined by a technical measurement prior to application of the fluid onto the wafer surface. In this embodiment the viscosimeter 6 is provided between the outlet of the pump 5 and the dispensing nozzle 4 in the feed 9. The viscosimeter is arranged inline, that is to say the actual viscosity of the fluid flowing in the feed 9 is measured during the operation of the apparatus 1. Particularly suitable for this purpose are viscosimeters such as are commercially available from the applicants. These viscosimeters are, for example, disclosed in U.S. Pat. No. 6,640,617 (P.7176).

This is a rotational viscosimeter. It includes an electrical rotary drive with a stator having a stator winding and a body of rotation rotatable in the fluid. The body of rotation is designed as the rotor of the rotary drive and is magnetically journalled in contact-free manner with respect to the stator.

In the embodiment shown in FIG. 1, the viscosimeter 6 is connected signal-wise with a control device 10 via a data line S1 in order to transfer the respective actual value of the viscosity of the fluid determined by a technical measurement to the control device. The control device 10 is furthermore connected via a data line S2 to the drive device 3 for the rotary plate 2.

Between the viscosimeter 6 and the dispensing nozzle 4 a valve 7 is provided in the feed 9 and is designed as a three-way valve which connects the feed 9 selectively with the dispensing nozzle 4 or with a return 8. The valve 7 is connected via a data line S3 to the control device 10 so that it can be controlled by the control device 190. The return 8 can, as shown in FIG. 1, be connected to the source 20 so that the fluid, with an appropriate valve setting of the valve 7, can flow back through the return 8 to the source 20. It is, however, also possible for the return 8 to lead to a separate collecting container.

Since apparatuses and methods for rotational coating (spin coating) of a surface of a substrate are well known per se, for example from semiconductor technology, the principal way of operation will not be discussed in more detail in the following.

During the rotational coating, the wafer 11 is fixed on the rotary plate 2 (the chuck) for example by means of vacuum or suction technology. The rotary plate 2 is set rotating by means of the drive device 3. With the pump 5 a predeterminable quantity of a photoresist is conveyed from the source 20 to the dispensing nozzle 4 and from the dispensing nozzle 4 onto the wafer. Through the rotation of the rotary plate 2 with the wafer 11 the photoresist is uniformly distributed over the surface of the wafer. Any possible excess material is spun off from the wafer 11. The thickness and the homogeneity of the layer 12 which is produced depends on several factors, such as, for example, the speed of rotation of the rotary plate 2, the duration of the rotation, the temperature of the substrate 11, the environmental temperature of the substrate 11 and the viscosity of the fluid, here the photoresist. The viscosity of the photoresist depends in turn on a plurality of parameters, in particular on the temperature of the photoresist and of its composition. Thus, by way of example, the viscosity of the photoresist can change because the ratio of polymer and solvent changes. Such effects can indeed also occur within one supply container, for example because the generally larger polymer molecules are not homogenously distributed in the solvent. This can lead, when considered over the supply container, to local density fluctuations and thus also to viscosity changes. In order to obtain a solid layer after the application of the photoresist to the surface of the wafer 11, it is necessary to remove the solvent. A part of the solvent vaporizes normally during the spinning-on process. This can be assisted by a heatable rotary plate 2, by a subsequent heating of the wafer or by rotation of the rotary plate, typically at a reduced speed of rotation in comparison to the application phase.

In general it is known, for example with reference to empirical data, or it can be found by tests, how the parameters for the rotation of the rotary plate 2, i.e. in particular its speed of rotation and its acceleration must be set in order to realize the desired thickness of the layer 12 for a photoresist of given viscosity and with defined process parameters. In particular, it is important for the homogeneity of the layer thickness that the coating is carried out with the most precise possible maintenance of the parameters. If however variations in the characteristics of the photoresist arise in production, then this can lead to a faulty or non-satisfactory coating of the surface of the wafer 11, either because the layer thickness no longer has the preset value or because the variations in the layer thickness are too large. Such faults or imperfections in the layer 12 can only be detected in previous methods after manufacture of the layer 12. If necessary, countermeasures can admittedly be taken, however, the photoresist layer must be removed again from the already coated wafers 11 and a new photoresist layer must be applied.

In accordance with the invention a viscosimeter 6 is thus provided with which an actual viscosity can be physically measured prior to the application of a photoresist. In the embodiment shown in FIG. 1, the pump 5 pumps the photoresist through the feed 9 to the viscosimeter 6 where the actual viscosity of the photoresist is measured in line. The value of the viscosity determined by technical measurement is conveyed via the data line S1 to the control device 10. The control device 10 checks whether the actual value of the viscosity of the photoresist corresponds with the desired value.

Surprising in this connection is the recognition that changes in the viscosity can in particular be sufficiently accurately detected with the viscosimeter 6. It has for example been shown that, with the applicant's viscosimeters that are preferably used, fluctuations in the viscosity of only one part per thousand or less can be reliably detected or measured.

The respective desired value for the viscosity of the photoresist can be stored in the control device 10 in dependence on other parameters, for example in dependence on the wafer temperature, on the environmental humidity and/or on the environmental temperature during the coating on the nature of the photoresist etc.

Thus, before each coating of a wafer 11, a check can be made whether the actual value of the viscosity of the photoresist corresponds with the desired value for the respective conditions. Through this check, faulty or low quality coatings on the wafer 11 can at least be significantly reduced.

In the first embodiment in accordance with FIG. 1 the valve 7 is in a switching position in which the feed coming from the pump 5 is connected to the dispensing nozzle 4 and the flow connection to the return 8 is closed for the coating of the wafer 11. If the control device 10 detects that the actual value of the viscosity of the photoresist differs from the desired value, then it switches the valve 7 via the data line S3 into a position which connects the feed 9 coming from the pump 5 to the return 8, so that the fluid does not reach the dispensing nozzle 4. In this manner, a deficient coating of the wafer 11 can be avoided. Measures can then be taken to set the viscosity to the correct value again.

It is also possible for the control device 10 to change the speed of rotation of the rotary plate 2 via the drive device 3 for the compensation of the deviation of the actual viscosity from the desired value, so that the deviation of the viscosity is compensated via a change in the rotational speed of the rotary plate 2. Thus, if the control device finds, with respect to data transferred from the viscosimeter, that the actual viscosity deviates from the desired value, then it determines, for example with the aid of look-up tables, empirical values or calculations, which speed of rotation of the rotary plate 2 belongs to the actual value of the viscosity in order to realize the desired layer thickness and homogeneity. The control device 10 can then control the drive device 3 via the data line S2, which accelerates or brakes the rotary plate 2 to the speed of rotation that has been found. In practice, it has, for example, been shown that a deviation of the viscosity of 1% can readily be corrected by a correction of the speed of rotation by 0.5%. A viscosity which is 3% too high is, for example, compensated by an increase of the speed of rotation by 0.5×3%=1.5%. A viscosity which is too low by 2% is corrected by a reduction of the speed of rotation by 0.5×2%=1%.

Should it not be possible to compensate the change in the actual viscosity by a change in the speed of rotation, then the possibility always exists of conducting the photoresist via the valve 7 into the return 8.

In the following description of the further embodiments the same parts or equivalent parts are designated with the same reference numerals as in FIG. 1. The explanations with respect to the first embodiment thus apply in the same sense and manner also for the other embodiments. In the following comment will only be made on changes and distinctions in comparison to the first embodiment. Vice versa, some measures and designs of the embodiments described in the following can also be used for the first embodiment.

FIG. 2 shows a second embodiment of an apparatus in accordance with the invention for rotational coating. In this embodiment a tempering device 15 is provided for changing the temperature of the fluid. The tempering device 15 includes a temperature control unit 153 with which at least one tempering element 151 can be controlled. The tempering element 151 stands in thermal contact with the fluid and can supply heat to the fluid in order to increase its temperature or remove heat in order to reduce its temperature. The tempering element 151 is arranged in the present case downstream of the viscosimeter 6 so that it can change the temperature of the fluid after leaving the viscosimeter and prior to reaching the dispensing nozzle 4.

Optionally, a tempering element 152 can alternatively or additionally be provided upstream of the viscosimeter 6 by which the temperature of the fluid can be changed before its entry into the pump. As a further variant it is also possible to change the temperature of the fluid in the source 20 as an alternative measure or as a supplementary measure.

The temperature control unit 153 is connected via a data line S5 to the control device 10.

Furthermore, in the second embodiment, a process chamber 13 is provided. The rotary plate with the substrate 11 is arranged inside the process chamber 13. Furthermore, a climate control unit 14 is provided with which at least the temperature in the process chamber 13 can be set. The climate control unit 14 can preferably also set further conditions, in particular atmospheric conditions in the process chamber, for example the humidity. The climate control unit 14 is connected signal-wise to the control device 10 via a data line S4.

Optionally, a return 8 and a valve for the opening of this return can also be provided in this embodiment.

During the operation, the actual value of the viscosity of the photoresist is in each case measured with the viscosimeter 6 and transferred to the control device via the data line S1. As soon as a deviation of the actual viscosity from the predetermined desired value is detected, the control device 10 can introduce one or more of the following compensations in order to counteract variation in the thickness of the layer 12 applied to the surface of the wafer 11.

As already described in the first embodiment, the control device can control the drive device 3 via the data line S2, so that it increases or reduces the speed of rotation of the rotary plate in order to compensate the change in the viscosity.

The control device 10 can so control the temperature control unit 153 via the data line S5 that it changes the temperature of the photoresist via the tempering element 151 in such a way that the viscosity readopts its desired value. With respect to the data stored in the control device the amount by which the temperature of the photoresist has to be increased or reduced can be found in simple manner, so that the actual value again comes into correspondence with the desired value. For the following coating processes, the temperature of the photoresist can then optionally be changed already in controlled manner with the tempering element 152 before the photoresist reaches the viscosimeter 6. In the viscosimeter 6 it can then be verified that the viscosity of the fluid actually has the desired value.

The control device can control the climate control unit 14 via the data line S4, so that it changes the temperature in the process chamber 13 and/or other parameters, such as for example the humidity, so that the changes caused by the deviation of the actual viscosity from the desired value can be compensated.

Naturally, other compensations are also possible in principle such as, for example, a heating or a cooling of the wafer 11 on the rotary plate 2.

It will be understood that measurement sensors can furthermore be provided in order to detect process parameters and to pass them on to the control device 10, for example sensors for the temperature of the fluid, for the environmental temperature in the process chamber 13 or for the surface temperature of the wafer.

The apparatus in accordance with the invention for rotary coating preferably has a supply unit 21 as the source for the fluid. FIG. 3 shows an embodiment of the supply unit which is designated as a whole with the reference numeral 21. The supply unit 21 is intended to make available the fluid, here the photoresist, for the coating of the wafer 11.

In particular, during rotational coating with polymer liquids, the fluid for the coating includes several components, namely at least one polymer and at least one solvent for the polymer. Accordingly, the supply unit 21 includes a first supply container 22 for a first component of the fluid and also a second supply container 23 for a second component of the fluid. In the present example the first component is the photoresist containing the polymer and the second component is the solvent for the polymer.

Each supply container 22, 23 is respectively connected via a line with a mixing device 24 in which the two components are intimately mixed with one another. The mixing device 24 includes an integrated or separate pump in order to pump the fluid or its components. This pump can be provided in addition to or as an alternative to the pump 5 (see FIGS. 1 and 2). The mixing device 24 can be designed as a dynamic mixer or as a pump with a static mixer connected downstream thereof.

From the mixing device 24 a line leads, via a filter 25 for filtering out of particles from the fluid, via a tempering unit 26 for heating or cooling of the fluid to the viscosimeter 6, where the actual value of the viscosity of the fluid is determined. A line leads from the outlet of the viscosimeter 6 to a liquid-flow meter 27 in order to detect by technical measurement the quantity of fluid that is flowing through and from there to a multi-way valve 28, here a three-way valve, which optionally connects the line coming from the liquid-flow meter 27 to a storage tank 29 or to a recirculation line 30 through which the fluid can flow back to the mixing device.

From the storage tank a line indicated by the arrow A then leads to the dispensing nozzle 4 which is not shown in FIG. 3. Further components, such as for example a further pump or a further tempering unit, can be provided between the storage tank 29 and the dispensing nozzle 4. Furthermore, a control and regulating unit 40 is provided which is connected signal-wise to the supply containers 22, 23, to the mixing device 24, to the filter 25, to the tempering unit 26, to the viscosimeter 6, to the liquid-flow meter 27 and to the multi-way valve 28, as is indicated in FIG. 3 by the broken lines.

The control device 10 (see FIG. 1, FIG. 2) is connected signal-wise with the control and regulating unit 40. Preferably the control device 10 is integrated into the control and regulating unit 40.

It will be understood that further shut-off, regulating or multi-way valves can be provided in order to control the flow of the fluid or its components.

In operation the control and regulating unit 40 now controls the two supply containers 22, 23 so that these respectively yield a quantity of the respective component to the mixing device suitable for the predeterminable mixing ratio of the components, with the two components being intimately mixed in the mixing device 24 in order to generate the fluid for the coating. This fluid is conveyed through the filter 25 to the tempering unit 26 where the fluid is brought to the predeterminable temperature. Thereafter, the actual value of the viscosity is determined by technical measurement in the viscosimeter 6 and is communicated to the control and regulating unit 40. After flowing through the liquid-flow meter 27, the fluid reaches the multi-way valve 28. If the control and regulating unit has found that the actual value of the viscosity of the fluid corresponds to the desired value, then it switches the multi-way valve 28 into the position in which the fluid can flow into the storage tank 29 in order to be conveyed from there to the dispensing nozzle 4.

If the control and regulation unit has determined that the actual value of the viscosity differs from the desired value, then it controls the multi-way valve 28 so that it closes the flow connection to the storage tank 29 and instead opens the flow connection into the circulation line 30 so that the fluid flows back into the mixing device 24.

For the compensation of the deviation of the actual viscosity from a desired value of the viscosity, the control and regulating unit 40 can control the tempering unit 26 so that this heats the fluid to a higher temperature or cools it down to a lower temperature in order in this way to change the actual viscosity of the fluid so that it corresponds with the desired value.

Alternatively or as a supplement to this, the possibility exists that the control and regulating unit so controls the first and the second storage container that the quantity ratio of the components of the fluid is set to a different value. If, for example, the actual value of the viscosity of the fluid is too high, the control and regulating unit can control the first and/or the second supply container 22, 23 so that the proportion of solvent in the photoresist is increased, whereby its actual viscosity is reduced.

The fluid, here the photoresist, is recirculated in the supply unit 21 until the actual value of the viscosity corresponds with the preset desired value and it is only then directed into the storage tank in order to be available for the rotary coating.

It will be understood that in the embodiment of FIG. 3 the speed of rotation, i.e. the rotary speed of the rotary plate 2, can be changed in order to compensate for deviations in the actual viscosity of the fluid from the desired value.

In the following a further embodiment of a method in accordance with the invention will be explained in more detail. The reference numerals and explanations with respect to the previous embodiments apply in the same sense and manner for this embodiment, too. In this embodiment the fluid for the coating is a photoresist comprising a solid. As an example the solid is a polymer and the fluid further comprises a solvent for the polymer.

As in the embodiments described herein before, prior to the application of the fluid its actual viscosity is determined by a physical measurement by means of a viscosimeter 6 and the actual viscosity of the fluid is compared with the desired value by means of a control device 10 which is connected signal-wise to the viscosimeter 6 and, in the case of a deviation, a compensation is introduced with which variations in the thickness of the layer 12 to be applied to the surface is counteracted. In this preferred embodiment said compensation is based upon the relationship

t=K*S*η^{1/3}*ω^{-2/3}*R^{-2/3}

where t represents the thickness of the layer 12, K being a constant, S represents the fraction of said solid in the fluid, η represents the dynamic viscosity of the fluid, c represents the rotational speed of the rotary plate 2, and R designates the radius of the substrate.

The thickness of the layer 12 or the film thickness is mathematically modeled in this nonlinear form:

t=K*S*η^{1/3}*ω^{-2/3}*R^{-2/3} (1)

Without any restriction to the generality it is assumed that the radius R of the substrate 11, i.e. the radius of the wafer, is a constant Rₒ.

The nonlinear equation in (1) can be linearized as follows:

t=tₒ+Δt=K*Sₒ*ηₒ^{1/3}*ωₒ^{-2/3}*Rₒ^{-2/3}+K₁*ΔS+K₂*Δη+K₃*Δω (2)

where tₒ≡K*Sₒ*ηₒ^{1/3}*ωₒ^{-2/3}*Rₒ^{-2/3}. The index ‘o’ indicates the respective value of t, S, η, ω at an operating point, practically a target film thickness and Δt, ΔS, Δη, Δω denotes the deviation of the respective variable from its value at the operating point.

In addition:

$${K}_{1} = \frac{\partial t}{\partial S} {\vert}_{S = {S}_{o} , η = {η}_{o} , ω = {ω}_{o}} , \\ {K}_{2} = \frac{\partial t}{\partial η} {\vert}_{S = {S}_{o} , η = {η}_{o} , ω = {ω}_{o}} , \\ {K}_{3} = \frac{\partial t}{\partial ω} {\vert}_{S = {S}_{o} , η = {η}_{o} , ω = {ω}_{o}} .$$

Rewriting Equation (2),

Δt=K₁*ΔS+K₂*Δη+K₃*Δω. (3)

As seen in Equation (3), there are three ‘knobs’ to adjust Δt: ΔS, Δη, and Δω. Practically, it is easy to accurately control ω. ΔS and Δη are given arbitrary in practice to a film coating system. However, the deviations ΔS and Δη of the fraction of solid S and of the viscosity η may be controlled, for example as it is explained herein before with respect to the other embodiments.

A simple solution to achieve Δt=0, in other words, to maintain a target film thickness of the layer 12 should be to adjust Δω such a way that the effects of ΔS and Δη may be compensated. In other words, Δt=0, if Δω is chosen as follows:

Δω=−(K₁*ΔS+K₂*Δη)/K₃ (4)

From a control engineering point of view, the system in Equation (3) can be modeled in a block diagram form as shown in FIG. 4.

In FIG. 4, Δω and Δt can be considered as an input and an output, and ΔS and Δη can be treated as external disturbances, and transfer functions are defined as Gₚ≡K₃, Gₛ≡K₁, G_{η}≡K₂. If ΔS and Δω are measured precisely and if all of the transfer functions are found accurately, then Δω in Equation (4) may achieve Δt=0.

FIG. 5 shows an embodiment for the concept of a film thickness control system in an open loop fashion in FIG. 4 with application to rotational coating. The apparatus is quite similar to the apparatus shown in FIG. 1.

In FIG. 5, the pump 5 delivers a fluid such as photoresist from the source 20. The control device 10 gets the information about the actual value of S and η from a measuring device 61 for the determination of the percentage of solid in the fluid, for example a density measuring device, and from the viscometer 6, calculates rotational speed of the rotary plate 2, ω=ωₒ+Δω, where ωₒ is the rotational speed at the operating point explained in Equation (2) and where Δω is obtained by Equation (4), and provides the drive device with the calculated ω. The return 8 may be used for helping to make accurate measurements of the percentage of solid and viscosity in case of they are dependent on flow and/or S and η are out of range and cannot be compensated by ω. The valve 7 is normally closed with respect to the dispensing nozzle 4 and opens when Δt=0 is ensured and when the substrate is ready for coating. For precise dispensing of a liquid through the nozzle 4, a metering pump (not shown) may be added additionally in an appropriate location in the flow channel in FIG. 5.

Typically, S and η are dependent from each other. Then S can be a function of η, and the film thickness of the layer 12 in equation (1) for a given wafer radius Rₒ becomes in a general form as follows:

t=f(η,ω) (4)

where f denotes a function.

And (4) can be linearized as follows:

t=tₒ+Δt=f(ηₒ,ωₒ)+Kₐ*Δη+K_{b}*Δω, (5)

where tₒ≡f(ηₒ, ωₒ) is an operating point, practically a target film thickness, and

$${K}_{a} = \frac{\partial t}{\partial η} {\vert}_{η = {η}_{o} , ω = {ω}_{o}} , \\ {K}_{b} = \frac{\partial t}{\partial ω} {\vert}_{η = {η}_{o} , ω = {ω}_{o}} .$$

Rewriting Equation (5), yields

Δt=Kₐ*Δη+K_{b}*Δω. (6)

In order to achieve Δt=0, in other words, to maintain a target film thickness of the layer 12, Δω should be chosen as follows:

Δω=−(Kₐ*Δω)/K_{b} (7)

From a control engineering point of view, the system in Equation (6) can be modeled in a block diagram form as shown in FIG. 6.

FIG. 7 shows an embodiment of the concept of a film thickness control system as illustrated in FIG. 6 with application to rotational coating (spin coating).

In FIG. 7, the control device 10 gets the actual value of the viscosity η from the viscosimeter 6, calculates rotational speed of the rotary plate 2, ω=ωₒ+Δω, where ωₒ is the rotational speed at the operating point explained in Equation (5) and where Δω is obtained by Equation (7), and provides the drive device with the calculated ω.

In practice, there may exist or occur modeling uncertainties in the transfer functions in FIG. 4. To improve robustness against the model uncertainties, a feedback control can be provided as shown in the block diagram in FIG. 8. With an appropriate film thickness measurement device 62, the feedback control system can be implemented. Its performance to follow a target film thickness (Δt=0) under the existence of external disturbances (ΔS and Δη) depends on the design of G_{c}, a feedback controller, and its robustness against modeling uncertainties improves owing to the feedback controller. In this implementation, ΔS and Δη do not have to be measured.

FIG. 9 shows an embodiment of the concept of a film thickness control system in a closed loop fashion illustrated in FIG. 8 with application to rotational coating. The control device 10 gets the information about the film thickness t of the layer 12 from thickness measurement device 62, calculates rotational speed of the rotary plate, ω=ωₒ+Δω, where ωₒ is the rotational speed at the operating point explained in Equation (2) and where Δω=−G_{c}*Δt, and provides the drive device 3 with the calculated ω.

1. An apparatus for the rotational coating of a surface of a substrate with a fluid, in particular the surface of a wafer with a polymer liquid, especially with a photoresist, the apparatus including a rotary plate (2) for receiving the substrate (11), a drive device (3) for rotating the rotary plate (2), a dispensing nozzle (4) for the application of a predeterminable quantity of fluid onto the surface of the substrate (11) for the purpose of forming a layer (12) and also a pump (5) for conveying the fluid, the pump being connectable, on the one hand, to a source (20) for the fluid and, on the other hand, to the dispensing nozzle (4), characterized in that a viscosimeter (6) is provided with which the actual viscosity of the fluid can be determined by physical measurement prior to the application of the fluid.

2. An apparatus in accordance with claim 1, having a control device (10) which is connected signal-wise to the viscosimeter and on deviation of the actual viscosity of the fluid from a desired value introduces a compensation which counteracts variations in the thickness of the layer (12) to be applied to the surface.

3. An apparatus in accordance with claim 1, in which a tempering device (5) is provided for changing the temperature of the fluid.

4. An apparatus in accordance with claim 1, wherein the rotary plate (2) for receiving the substrate (11) is provided in a process chamber (13) and having a climate control unit (14), with which at least the temperature in the process chamber (13) can be set.

5. An apparatus in accordance with claim 1, in which a supply unit (21) is provided as the source for the fluid having a first supply container (22) for a first component of the fluid, a second supply container (23) for a second component of the fluid, a mixing device (24) for the mixing of the components of the fluid and also with a control and regulation unit (40), with which the quantity ratio of the components of the fluid can be set.

6. An apparatus in accordance with claim 5, in which the viscosimeter (6) is provided in the supply unit (21).

7. An apparatus in accordance with claim 2, in which the compensation includes at least one of the following measures: changing the temperature of the fluid, changing the speed of rotation of the rotary plate (2), changing the temperature in the process chamber (13); changing the composition of the fluid by changing the quantity ratio of the components of the fluid.

8. A method for the rotational coating of a surface of a substrate with a fluid, in particular of the surface of a wafer with a polymer liquid, especially with a photoresist, in which method the substrate (11) is arranged on a rotary plate (2), the rotary plate (2) is rotated, a predeterminable quantity of the fluid is applied with a dispensing nozzle (4) onto the surface of the substrate (11) for the purpose of formation of a layer (12), with the fluid being conveyed by means of a pump (5) from a source (20) for the fluid to the dispensing nozzle (4), characterized in that prior to the application of the fluid its actual viscosity is determined by a physical measurement by means of a viscosimeter (6).

9. A method in accordance with claim 8, in which the actual viscosity of the fluid is compared with the desired value by means of a control device (10) which is connected signal-wise to the viscosimeter (6) and, in the case of a deviation, a compensation is introduced with which variations in the thickness of the layer (12) to be applied to the surface is counteracted.

10. A method in accordance with claim 8, in which the actual viscosity is determined by a physical measurement by means of a viscosimeter (6) in a supply unit (21) provided as a source for the fluid.

11. A method in accordance with claim 9, in which at least one of the following measures is carried out as a compensation: change of the temperature of the fluid, change of the rotational speed of the rotary plate (2), change of the temperature in a process chamber (13) for the rotary plate (2), change of the composition of the fluid by changing the quantity ratio of components of the fluid.

12. A method for the rotational coating of a surface of a substrate with a fluid, in particular of the surface of a wafer with a polymer liquid, especially with a photoresist, said fluid comprising a solid, in which method the substrate (11) is arranged on a rotary plate (2), the rotary plate (2) is rotated, a predeterminable quantity of the fluid is applied with a dispensing nozzle (4) onto the surface of the substrate (11) for the purpose of formation of a layer (12), with the fluid being conveyed by means of a pump (5) from a source (20) for the fluid to the dispensing nozzle (4), wherein prior to the application of the fluid its actual viscosity is determined by a physical measurement by means of a viscosimeter (6) and wherein the actual viscosity of the fluid is compared with the desired value by means of a control device (10) which is connected signal-wise to the viscosimeter (6) and, in the case of a deviation, a compensation is introduced with which variations in the thickness of the layer (12) to be applied to the surface is counteracted, said compensation being based upon the relationship
t=K*S*η^{1/3}*ω^{-2/3}*R^{-2/3}
where t represents the thickness of the layer (12), K being a constant, S represents the fraction of said solid in the fluid, η represents the dynamic viscosity of the fluid, ω represents the rotational speed of the rotary plate (2), and R designates the radius of the substrate.

13. A method in accordance with claim 12 wherein said compensation comprises changing the fraction of said solid in the fluid.

14. A method in accordance with claim 13 wherein the fraction of said solid is determined by a physical measurement.

15. A method in accordance with claim 12 wherein the relationship
t=K*S*η^{1/3}*ω^{-2/3}*R^{-2/3}
for the thickness of the layer is linearized.

16. A method in accordance with claim 12 wherein a closed loop control is provided for controlling the thickness of the layer 12.
